(19) United States
(12) Patent Application Publication
(10) Pub. No.: US 2008/0160692 A1
(43) Pub. Date: Jul. 3, 2008

(54) Method for Manufacturing Flash Memory Device

(76) Inventor: JI HO HONG, Hwaseong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/929,948

(22) Filed: Oct. 30, 2007

(30) Foreign Application Priority Data
Dec. 27, 2006 (KR) 10-2006-0135752

(51) Int. Cl. H01L 21/336

(52) U.S. Cl. 438/261; 257/E21.422

(57) ABSTRACT

Provided is a method for manufacturing a flash memory device that can improve uniformity. In one method, an oxide chemical mechanical polishing process is performed to remove a height difference of the interlayer insulating layer that is generated between the cell area and the peripheral area due to the gate stack formed in the cell area that is not formed in the peripheral area.

### CROSS-REFERENCE TO RELATED APPLICATION

The present application claims the benefit under 35 U.S.C. §119 of Korean Patent Application No. 10-2006-0135752, filed Dec. 27, 2006, which is hereby incorporated by reference in its entirety.

### BACKGROUND

A flash memory device is a non-volatile memory medium where stored data is not damaged even when the power is turned off. In addition, flash memory typically has high processing speeds for writing, reading, and deleting data. Therefore, flash memory is widely used for storing data in basic input output systems (BIOSs) of personal computers (PCs), settop boxes, printers, and network servers, and recently, widely used for digital cameras and cellular phones.

FIG. 1 is a cross-sectional view of a related art flash memory device.

Referring to FIG. 1, the related art flash memory device is divided into a cell area and a peripheral area. The cell area is designed for the writing and deleting data, and the peripheral area is designed for operating a transistor depending on writing and deleting of data.

A device isolation layer 2 is formed in each area of the substrate 1. A first polysilicon layer 4, an oxide-nitride-oxide (ONO) layer 5, a second polysilicon layer 6, and spacers 7 are formed in the cell area of the substrate 1. The second polysilicon layer 6 and spacers 7 are also formed in the peripheral area for the transistor, and impurity regions 9 are formed for the transistor.

In the cell area, the first polysilicon layer 4 serves as a floating gate, and the second polysilicon layer 6 serves as a control gate. In the peripheral area, the second polysilicon layer 6 serves as a gate for a transistor.

Since the cell area further includes the ONO layer 5 and the second polysilicon layer 6 on the ONO layer 5 compared to the peripheral area as described above, a height difference is generated by the entire thickness of the ONO layer 5 and the second polysilicon layer 6 in the cell region when a pre-metal dielectric (PMD) material 8 is deposited on the substrate 1.

Generally, a chemical mechanical polishing (CMP) process is performed on the PMD material to obtain a planarized interlayer insulating layer.

However, planarizing the PMD material 8 deposited on the substrate 1 using the CMP process is not easy due to the height difference d between the cell area and the peripheral area.

That is, in the case where the CMP process is performed on the PMD material 8, a portion of the PMD material located in the cell area should be polished first. However, since the PMD materials in the cell area and the peripheral area are polished simultaneously in an actual process, an interlayer insulating layer becomes non-uniform over the cell area and the peripheral area even after the CMP process. Consequently, even after the CMP process has been performed, the heights of the cell area and the peripheral area are not the same, which may generate a defective contact formed during a subsequent process.

Particularly, in the case where an integration degree of a flash memory device is high, non-uniformity between the cell area and the peripheral area has a fatal adverse influence on device characteristics.

### BRIEF SUMMARY

Embodiments of the present invention provide a flash memory device and a method for manufacturing the flash memory device that can improve uniformity between a cell area and a peripheral area. According to an embodiment, uniformity between the cell area and the peripheral area can be improved by a particular planarizing of an interlayer insulating layer before forming a contact plug.

In one embodiment, a method for manufacturing a flash memory device includes: forming a first polysilicon layer pattern and an oxide-nitride-oxide layer pattern in a cell area of a substrate; forming a second polysilicon layer pattern in the cell area and a peripheral area of the substrate; forming spacers on both sides of the second polysilicon layer pattern, forming source/drain regions in the substrate; forming an interlayer insulating layer on the substrate; and performing an oxide chemical mechanical polishing process to remove a height difference of the interlayer insulating layer generated between the cell area and the peripheral area.

The details of one or more embodiments are set forth in the accompanying drawings and the description below. Other features will be apparent from the description, drawings, and the appended claims.

### BRIEF DESCRIPTION OF THE DRAWINGS

FIG. 1 is a cross-sectional view of a related art flash memory device.

FIGS. 2A to 2E are cross-sectional views illustrating a process for manufacturing a flash memory device according to an embodiment of the present invention.

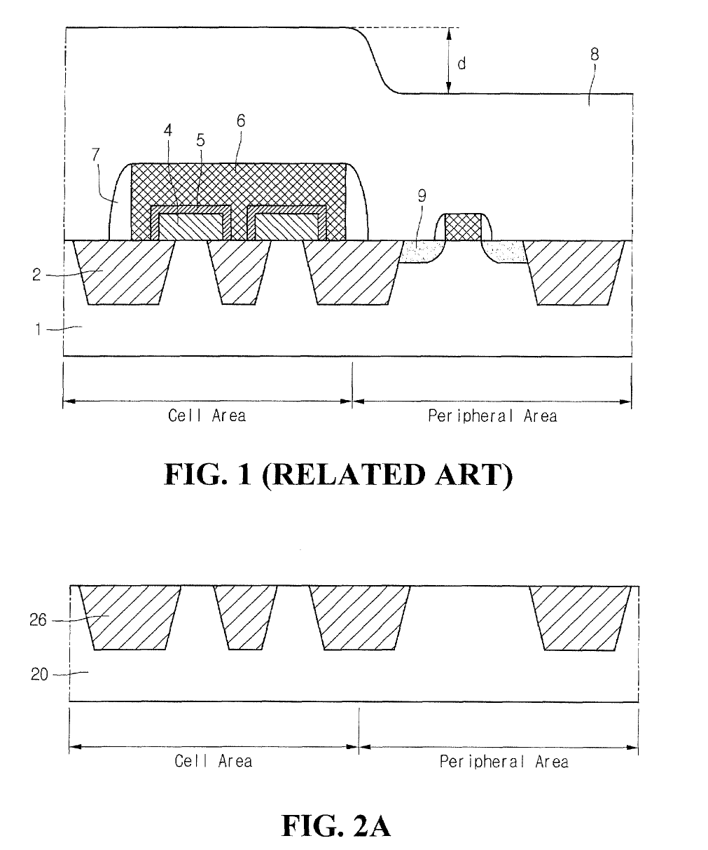

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

Reference will now be made in detail to the embodiments of present disclosure, examples of which are illustrated in the accompanying drawings.

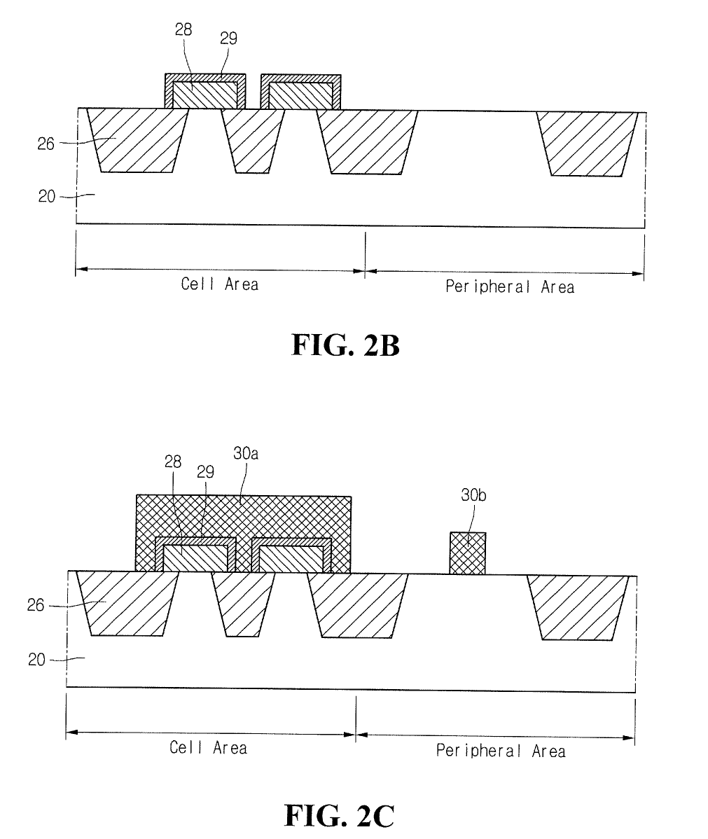

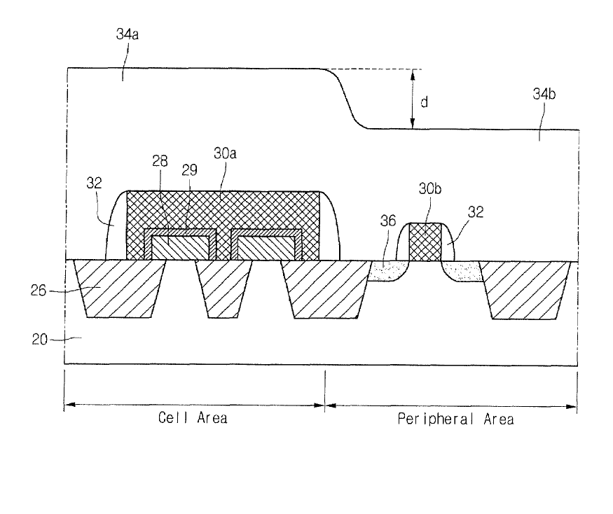

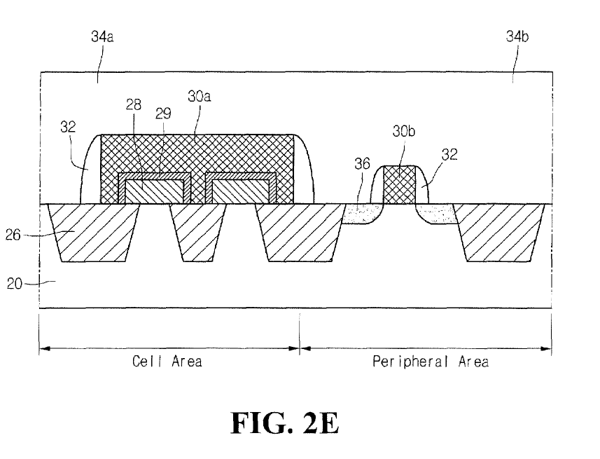

FIGS. 2A to 2E are cross-sectional views illustrating a process for manufacturing a flash memory device according to an embodiment.

Referring to FIG. 2A, a semiconductor substrate 20 can be prepared, and a cell area and a peripheral area can be defined in the semiconductor substrate 20.

Device isolation layers 26 can be formed in the substrate 20. In one embodiment, to form to device isolation layers, the semiconductor substrate 20 is patterned to form trenches. Then, borophosphosilicate glass (BPSG) or a silicon oxide layer can be used to gap-fill the trenches, and a CMP process is performed to provide the device isolation layers 26.

The device isolation layers 26 isolate devices formed in the semiconductor substrate during a subsequent process.

An oxide layer (not shown) can be formed on the semiconductor substrate 20.

An ion implantation process can be performed on the semiconductor substrate 20 including the device isolation layer 26 to form well regions in the semiconductor substrate 20.

Referring to FIG. 2B, polysilicon can be formed and patterned on the semiconductor substrate 20 to form a first polysilicon layer pattern 28 in the cell area. The first polysilicon layer pattern 28 can be used as a floating gate. A gate oxide layer can be formed before forming the first polysilicon layer pattern 28.

Subsequently, in an embodiment, a first oxide, a nitride, and a second oxide can be formed on the semiconductor substrate 20 including the first polysilicon layer pattern 28, and annealed and patterned to form an ONO layer 29 on the first polysilicon layer 28 in the cell area. The first polysilicon layer pattern 28 can be surrounded by the ONO layer 29. The first polysilicon layer pattern 28 can be doped with dopants, so that charges (or electrons) exist in an excited state inside the first polysilicon layer pattern 28.

Referring to FIG. 2C, polysilicon can be formed and patterned on the semiconductor substrate 20 including the ONO layer 29 to form second polysilicon layer patterns 30a and 30b in the cell area and the peripheral area, respectively. The second polysilicon layer pattern 30a formed in the cell area can be used as a control gate, and the second polysilicon layer pattern 30b formed in the peripheral area can be used as a gate for a transistor.

The second polysilicon layer pattern 30a in the cell area can be formed to cover the ONO layer 29, and the second polysilicon layer pattern 30b in the peripheral area is directly formed as a pattern on the semiconductor substrate 20 with a gate insulating layer (not shown) therebetween.

The second polysilicon layer pattern 30a formed in the cell area can be used to apply a bias voltage to excite electrons in the first polysilicon layer pattern 28 to perform charging or discharging.

Referring to FIG. 2D, a silicon oxide, a silicon nitride, and a silicon oxide can be sequentially formed and patterned on the semiconductor substrate 20 including the second polysilicon layer patterns 30a and 30b to form spacers 32 on sides of the second polysilicon layer patterns 30a and 30b. Accordingly, in an embodiment, the spacers can have a three-layer structure of the silicon oxide, silicon nitride, and silicon oxide.

Though the spacers 32 have been described to have the three-layer structure of the silicon oxide, silicon nitride, and silicon oxide embodiments are not limited thereto. For example, the spacers 32 can have a two-layer structure of a silicon nitride and a silicon oxide.

An ion implantation process can be performed using the spacers 32 and the second polysilicon layer patterns 30a and 30b as a mask to form source/drain regions 36 in the semiconductor substrate 20.

After that, an interlayer insulating layer (34a and 34b) can be formed using, for example, undoped silicate glass (USG) or borophosphosilicate glass (BPSG) on the semiconductor substrate 20.

Since the second polysilicon layer pattern 30a in the cell area is formed on both the ONO layer 29 and the first polysilicon layer pattern 28, the second polysilicon layer pattern 30a is formed at a higher position than that of the second polysilicon layer pattern 30b in the peripheral area by the heights of the ONO layer 29 and the first polysilicon layer pattern 28.

Accordingly, when the interlayer insulating layer (34a and 34b) is formed on the second polysilicon layer patterns 30a and 30b, a height difference d is generated between the cell area and the peripheral area. That is, since the first polysilicon layer pattern 28 and the ONO layer 29 that are not present in the peripheral area are formed in the cell area, the interlayer insulating layer 34a is formed higher than the interlayer insulating layer 34b by the heights of the first polysilicon layer pattern 28 and the ONO layer 29, and accordingly, the height difference d is generated between the interlayer insulating layer 34a in the cell area and the interlayer insulating layer 34b in the peripheral area.

Referring to FIG. 2E, an oxide CMP process can be performed on the interlayer insulating layers 34a and 34b to polish the interlayer insulating layer 34a in the cell area such that the height of the interlayer insulating layer 34a in the cell area reduces to that of the interlayer insulating layer 34b in the peripheral area.

The conditions of the oxide CMP process can include a down pressure in the range of 270-330 g/cm², a backside pressure in the range of 90-110 g/cm², a pad rotation speed in the range of 70-90 rpm, a head rotation speed in the range of 70-90 rpm, a slurry flow rate in the range of 160-240 ml/min, an additive flow rate in the range of 17-23 ml/min, and a processing time in the range of 100-250 seconds.

The oxide CMP process can use an oxide pad to polish the substrate.

The interlayer insulating layer 34a in the cell area can be easily reduced to the height of the interlayer insulating layer 34b in the peripheral area using the above-described oxide CMP process.

The height of the interlayer insulating layer 34a in the cell area can be reduced to the height of the interlayer insulating layer 34b in the peripheral area to remove the height difference d between the cell area and the peripheral area, so that the interlayer insulating layer (34a and 34b) has a same height over the cell area and the peripheral area to improve uniformity between the cell area and the peripheral area.

Subsequently, though not shown, the interlayer insulating layer (34a and 34b) can be selectively etched to form via holes, and contact plugs can be formed in the via holes to electrically connect the second polysilicon layer patterns 30a and 30b and the source/drain regions 36 to the appropriate signal paths. Accordingly, a flash memory device can be manufactured.

As described above, according to embodiments of the present invention, the height difference generated between the interlayer insulating layers in the cell area and the peripheral area can be removed, so that uniformity between the cell area and the peripheral area can be improved.

Therefore, a defective contact frequently generated when a contact plug is formed in a subsequent process can be prevented.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a flash memory device, comprising:
forming an interlayer insulating layer on a substrate provided with a cell area and a peripheral area; and
performing an oxide chemical mechanical polishing process to remove a height difference of the interlayer insulating layer between the cell area and the peripheral area.

2. The method according to claim 1, wherein the interlayer insulating layer in the cell area is polished by the oxide chemical mechanical polishing process.

3. The method according to claim 2, wherein the interlayer insulating layer in the cell area is polished to have the same height as the interlayer insulating layer in the peripheral area.

4. The method according to claim 1, wherein performing the oxide chemical mechanical polishing process comprises using a down pressure in the range of 270-330 g/cm², a backside pressure in the range of 90-110 g/cm², a pad rotation speed in the range of 70-90 rpm, a head rotation speed in the range of 70-90 rpm, a slurry flow rate in the range of 160-240 ml/min, an additive flow rate in the range of 17-23 ml/min, and a processing time in the range of 100-250 seconds.

5. The method according to claim 1, wherein the oxide chemical mechanical polishing process uses an oxide pad.

6. The method according to claim 1, further comprising:
patterning the interlayer insulating layer to form via holes; and
forming contact plugs in the via holes.

7. The method according to claim 1, further comprising:
forming a first polysilicon layer pattern for a floating gate and an oxide-nitride-oxide layer in the cell area of the substrate;
forming a second polysilicon layer pattern in the cell area for a control gate and the peripheral area for a transistor;
forming spacers on sides of the second polysilicon layer pattern; and
forming source/drain regions in the substrate;
wherein the interlayer insulating layer is formed on the second polysilicon layer pattern.
